(19) United States
(12) Patent Application Publication
(10) Pub. No.: US 2008/0086668 A1
(43) Pub. Date: Apr. 10, 2008

(54) MODEL-BASED TESTING METHOD AND SYSTEM USING EMBEDDED MODELS

(76) Inventors: Stanley T. Jefferson, Palo Alto, CA (US); Ajay Koche, San Jose, CA (US); Nicholas B. Tufillaro, Loveland, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/539,167

(22) Filed: Oct. 5, 2006

(51) Int. Cl. G01R 31/28

(52) U.S. Cl. 714/741

(57) ABSTRACT

A testing system and various methods involving testing of a device under test (DUT) use a device model to model a stimulus-response behavior of a the DUT. The testing system includes a device model of the DUT that is fitted to the stimulus-response behavior of the DUT and a measurement projector connected to an output of the device model. The device model includes a block diagram model and a difference model. Test metrics for the DUT are produced by the measurement projector from an output of the fitted device model.

### CROSS-REFERENCE TO RELATED APPLICATIONS

N/A

### STATEMENT REGARDING FEDERALLY SPONSORED RESEARCH OR DEVELOPMENT

N/A

### BACKGROUND

Testing a device is normally an integral part of the design, manufacture and maintenance of the device. Testing is routinely employed during the design of a new device to establish reliability and an operational capability of the device. In manufacture, testing establishes and/or quantifies operability of the device as well as facilitates yield improvements through failure diagnosis. Once the device is deployed, testing helps to maintain the device by detecting potential failures and diagnosing the cause or causes of failures of the device.

As competition persists in applying downward pressure on prices, interest continues in methods and strategies to reduce the time for, and improve the results of, testing in a production environment. In particular, there is considerable focus on costs associated with production testing of complex integrated circuits (ICs) such as, but not limited to, analog and mixed mode radio frequency ICs (RFICs) used in second and third generation cell phones, wireless data communications equipment, and related consumer electronics. Substantial costs are often incurred both in terms of test development and production test execution times for large volume consumer ICs (e.g., RFICs). These costs can have an adverse affect on an overall price of such ICs that ultimately may limit their acceptance and use in consumer electronics.

Given the importance and cost of testing complex ICs, numerous strategies have been and are being developed in an attempt to improve efficiency of such testing in a production environment. These strategies include, but are not limited to, test ordering, test subset selection, design for test, analog built-in self-test, the use of simulation to help identify faults, and other methods to evaluate and possibly improve the effectiveness of test suites employed in such testing. However, maintaining adequate levels of accuracy in the testing generally remains paramount in importance to ensure a given quality level of tested ICs for a specific operational situation, environment or application.

### BRIEF SUMMARY

In some embodiments of the present invention, a model-based testing system is provided. The model-based testing system comprises a device model that is fitted to a stimulus-response behavior of a device under test (DUT) to provide a fitted device model. The device model comprises a block diagram model and a difference model. The model-based testing system further comprises a measurement projector producing test metrics for the DUT from an output of the fitted device model.

In other embodiments of the present invention, a method of model-based testing a device under test (DUT) is provided. The method of model-based testing comprises constructing a device model comprising a block diagram model and a difference model. The method of model-based testing further comprises determining test metrics for the DUT using measurement projection of an output of the device model. Once constructed, a stimulus-response behavior of the device model essentially matches a stimulus-response behavior of the DUT.

In yet other embodiments of the present invention, a method of generating a model-based testing protocol is provided. The method of generating a model-based testing protocol comprises developing a block diagram model of a device type. The block diagram model models a signal path of the device type and the device type represents a device under test (DUT). The method of generating further comprises developing a difference model comprising a basis function and model parameters. The difference model accounts for a difference between a stimulus-response behavior of the block diagram model and a stimulus-response behavior of the DUT. The method of generating further comprises incorporating a device model into the testing protocol. The device model comprises the block diagram model and the difference model.

In yet other embodiments of the present invention, a method of model-based testing a device under test (DUT) is provided. The method of model-based testing comprises receiving a testing protocol comprising a device model. The device model comprises a block diagram model and a difference model. The method of model-based testing further comprises fitting the device model to a stimulus-response behavior of the DUT to produce a fitted device model.

Certain embodiments of the present invention have other features that are one or both of in addition to and in lieu of the features described above. These and other features of the invention are detailed below with reference to the following drawings.

### BRIEF DESCRIPTION OF THE DRAWINGS

The various features of embodiments of the present invention may be more readily understood with reference to the following detailed description taken in conjunction with the accompanying drawings, where like reference numerals designate like structural elements, and in which:

FIG. 1 illustrates a block diagram of a model-based testing system according to an embodiment of the present invention.

FIG. 2 illustrates a block diagram of a device model according to an embodiment of the present invention.

FIG. 3 illustrates a block diagram of a typical direct conversion receiver used in a third generation cell phone.

FIG. 4 illustrates a flowchart of a method of model-based testing of a device under test (DUT), according to an embodiment of the present invention.

FIG. 5 illustrates a flowchart of constructing a device model in the method of FIG. 4, according to an embodiment of the present invention.

FIG. 6 illustrates a flowchart of determining test metrics in the method of FIG. 4, according to an embodiment of the present invention.

FIG. 7 illustrates a flowchart of a method of generating a model-based testing protocol according to an embodiment of the present invention.

FIG. 8 illustrates a flowchart of a method of model-based testing of a device under test (DUT), according to an embodiment of the present invention.

### DETAILED DESCRIPTION

The embodiments of the present invention facilitate testing a device under test (DUT) that one or both of employs and operates upon either an analog signal or both an analog signal and a digital signal (i.e., mixed signals). The DUT is one of a plurality of devices of a device type such that the device type represents a particular device design of the DUT. A device model of the device type is developed and is fitted to emulate a stimulus-response behavior of the actual DUT. The device model is a behavioral model that depends on a set of parameters. As such, the device model may be termed a ‘behavioral parametric model’. Herein, the device model is also referred to as an ‘embedded model’, the meaning of which is discussed below. Once fitted, the device model is employed to determine test metrics of the DUT.

According to the present invention, the device model is fitted to emulate a stimulus-response behavior of the actual DUT. In general, fitting estimates or otherwise determines values for the parameters of the device model such that the stimulus-response behavior of the device model essentially matches the stimulus-response behavior of the actual DUT. In some embodiments, the device model is fitted using a relatively small number of data samples representing the stimulus-response behavior of the actual DUT. Once determined, the parameters of the device model facilitate determining, directly or indirectly, the test metrics of the DUT.

In some embodiments, the DUT is a device or a subsystem that exhibits complex stimulus-response functionality. The exhibited complex stimulus-response functionality is characterized by multiple time scales and frequency scales, in some embodiments. For example, signals entering and exiting such a DUT (i.e., stimulus and response signals) may be at, or have one or both of, different time scales and different frequency scales. Furthermore, in some embodiments, the DUT is a multiport device. Examples herein are intended to be illustrative only and are presented for discussion purposes and not by way of limitation.

Exemplary of multiport DUTs that exhibit a complex stimulus-response behavior are various analog integrated circuits (ICs) typically found in second and third generation cell phones. Second and third generation cell phones employ complex digital modulation formats such as, but not limited to, wideband code division multiple access (WCDMA) modulation. An example of such a third generation cellular telephone analog IC is a direct conversion WCDMA complimentary metal oxide semiconductor (CMOS) receiver discussed in more detail below.

Testing of the DUT according to some embodiments of the present invention ultimately produces test metrics that characterize a performance of the DUT. The metrics associated with the testing largely depend on the type of DUT being tested as well as depend on an application of the DUT. An example of a test metric for the direct conversion WCDMA CMOS receiver is a compression point of a channel of the receiver. Another exemplary test metric a power spectral density. Yet another exemplary test metric may characterize one or both of a linear and a nonlinear performance of the DUT. In some embodiments, the present invention facilitates DUT testing that is adapted to a production test environment.

According to some embodiments of the present invention, the DUT is tested by applying a stimulus signal S(t) to the DUT and producing a response signal R(t) from the DUT. In some embodiments, both the stimulus signal S(t) and the response signal R(t) are time domain signals. A time domain signal is a signal that is represented as a function of a time variable t (e.g., the signal S(t) varies as a function of the time variable t). In some embodiments, one or both of the stimulus signal S(t) and the response signal R(t) are complex signals having a real part and an imaginary part (e.g., R(t)=R [symbol] (t)+R [symbol] (t), R [symbol] (t)=real part and R [symbol] (t)=imaginary part).

In some embodiments, one or both of the stimulus signal S(t) and response signal R(t) are time sampled. In some embodiments, one or both of the stimulus signal S(t) and the response signal R(t) are recorded for later use. For example, the response signal R(t) may be recorded by time-sampling an output of the DUT and storing the time-samples in memory. Time-sampling may comprise using an analog to digital converter (ADC) to digitize a signal, for example. Similarly, the stimulus signal S(t) may be time-sampled. Herein, no distinction is made between a signal itself, a time sampled version of the signal, and a stored version of the signal unless such a distinction is necessary for proper understanding of that being described.

The stimulus signal S(t) and the response signal R(t) are then used to fit the device model. In some embodiments, the device model is fitted to data representing the stimulus-response of the DUT such that the device model essentially tracks a performance thereof. That is, the fitted device model has a stimulus-response behavior that emulates the stimulus-response behavior of the DUT itself.

Once fitted, an output of the device model is employed to generate one or more test metrics for the DUT. Herein, generating the test metrics from the device model output is referred to as ‘measurement projection’. In some embodiments, the output of the device model comprises one or both of an output signal of the device model when stimulated by the stimulus signal S(t) and a model parameter of the fitted device model (i.e., one or more model parameters of the device model after fitting). The one or both of the output signal and the fitted model parameters are employed to compute or otherwise generate the test metrics. Essentially, the test metrics are generated as a measurement projection of the device model output. In other words, the output signal and the fitted model parameters are projected into a measurement space representing the desired test metrics for the DUT.

During measurement projection when a stimulus of the fitted device model is employed, the fitted device model is stimulated and the test metrics are computed from an output signal of the fitted device model. In some embodiments, the test metrics are determined directly from a response of the fitted device model to the stimulus signal S(t) used in the above-mentioned fitting. In other embodiments, a different stimulus signal S′(t) (i.e., S(t)≠S′ (t)) is employed to stimulate the fitted device model during measurement projection. Using the different stimulus signal S′(t) may facilitate determining specific test metrics, especially when such metrics are not readily available from a response of the fitted device model to the stimulus signal S(t).

In some embodiments, the fitted device model essentially recreates the stimulus-response behavior of the actual DUT. A response of the fitted device model to the different stimulus signal S′(t) essentially represents a response of the actual DUT to the different stimulus signal S′(t). Herein, the stimulus signal S(t) will generally be used to interchangeably denote the stimulus signal S(t) used in the fitting or the different stimulus signal S′(t) unless explicit differentiation between the signals is necessary for proper understanding.

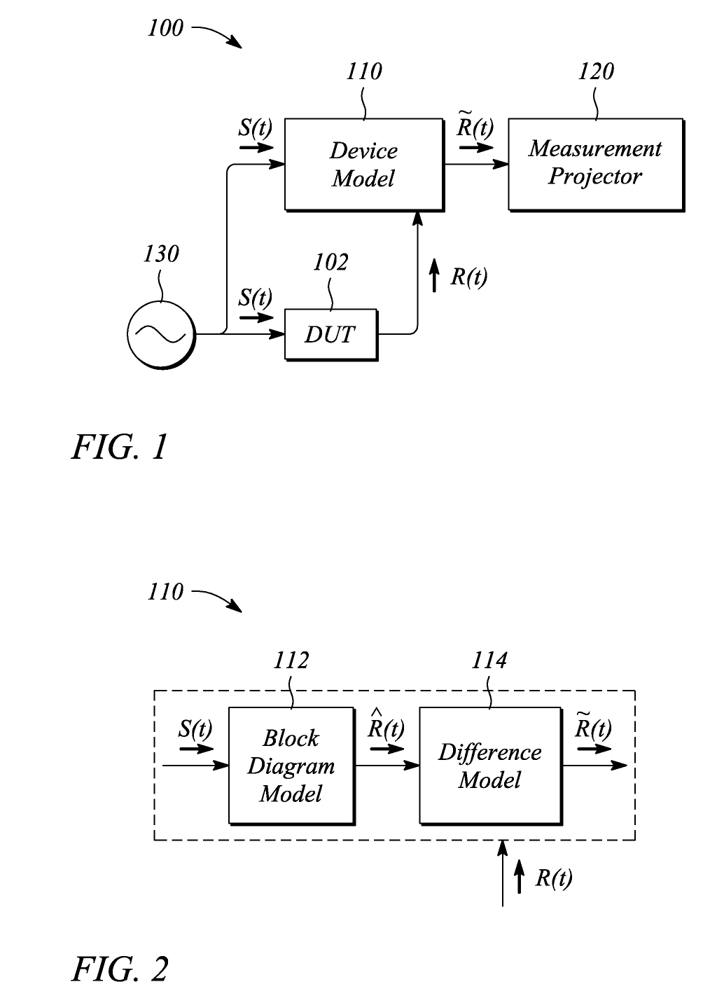

FIG. 1 illustrates a block diagram of a model-based testing system 100 according to an embodiment of the present invention. The model-based testing system 100 tests a DUT 102 and generates one or more test metrics for the DUT 102. The model-based testing system 100 comprises a device model 110 and a measurement projector 120. The device model 110 is a behavioral parametric model that is fitted to emulate a stimulus-response behavior of the DUT 102. The measurement projector 120 receives an output from the device model 110. The measurement projector 120 generates the one or more test metrics from the received output of the device model 110 using measurement projection.

As illustrated in FIG. 1, the DUT 102 accepts the applied stimulus signal S(t) and produces the response signal R(t). The stimulus signal S(t) and the response signal R(t) are applied to the device model 110 for fitting the device model 110 to the stimulus-response behavior of the DUT 102. In some embodiments, the stimulus signal S(t) is applied simultaneously to both the DUT 102 and the device model 110 (e.g., as illustrated in FIG. 1). In other embodiments, the application of the stimulus signal S(t) and the response signal R(t) to the device model 110 occurs at some time after the application of the stimulus signal S(t) to the DUT 102. For example, the stimulus signal S(t) may be applied first to the DUT 102 and the resulting response signal R(t) recorded or otherwise saved for later use. Subsequently, the stimulus signal S(t) (possibly also recorded) and the recorded response signal R(t) are applied to the device model 110.

During fitting, parameters of the device model 110 are adjusted such that a response signal of the device model 110 essentially matches the response signal R(t). Hereinafter, the response signal generated by the stimulated device model 110 is referred to as a stimulated response signal \tilde{R}(t).

Following fitting of the device model 110, the measurement projector 120 produces test metrics for the DUT 102 using a measurement projection of an output of the device model 110. In some embodiments, the measurement projector 120 employs one or more fitted parameters of the device model 110 for the measurement projection. In such embodiments, the ‘output’ of the device model 110 comprises fitted parameters of the fitted device model 110.

In other embodiments, the measurement projector 120 employs the stimulated response signal \tilde{R}(t) produced by the fitted device model 110 in response to an applied stimulus signal S(t) to produce the test metrics. In yet other embodiments, the measurement projector 120 employs a combination of the stimulated response signal \tilde{R}(t) and one or more of the fitted parameters of the device model 110 to produce the test metrics. In embodiments that employ a stimulus, the stimulus signal S(t) used in fitting or the different stimulus signal S′(t) is applied to the fitted device model 110 to produce the stimulated response signal \tilde{R}(t).

In some embodiments, the model-based testing system 100 further comprises a stimulus source 130. The stimulus source 130 produces one or both of the stimulus signals S(t) and S′(t). The stimulus source 130 is connected to an input of the device model 110. The stimulus source 130 further may be connected to and provide the stimulus signal S(t) to an input of the DUT 102, in some embodiments.

FIG. 2 illustrates a block diagram of a device model 110 according to an embodiment of the present invention. As illustrated in FIG. 2, the device model 110 comprises a ‘block diagram’ model 112. The block diagram model 112 is a model that is based on a signal path of the device type that represents the DUT 102. In particular, the block diagram model 112 models the device type, and by extension the DUT 102, at a ‘block diagram’ level. The device model 110 further comprises a difference model 114. The difference model 114 models a behavioral difference between the actual DUT 102 and the block diagram model 112 of the device model 110.

In some embodiments, the block diagram model 112 receives the stimulus signal S(t) from an input of the device model 110. In turn, the block diagram model 112 generates a response signal \hat{R}(t). The response signal \hat{R}(t) is communicated to and serves as an input signal to the difference model 114. The stimulated response signal \tilde{R}(t) is produced by difference model 114, in such embodiments.

During fitting, parameters of the device model 110 are adjusted. In some embodiments, the parameters of the device model 110 that are adjusted comprise parameters of the difference model 114. In other embodiments, the adjusted parameters comprise parameters of both the block diagram model 112 and the difference model 114. Parameters of the device model 110 are adjusted until a performance of the device model 110 essentially matches a respective performance of the DUT 102. When the respective performances of the device model 110 and the DUT 102 essentially match, the device model 110 is a fitted device model 110.

Whether or not the respective performances of the device model 110 and the DUT 102 essentially match is determined by comparing an output of the device model 110 to an output of the DUT 102. In some embodiments, the compared outputs are the response signals, \tilde{R}(t) and R(t). In such embodiments, the stimulated response signal \tilde{R}(t) at an output of the difference model 114 is compared to the response signal R(t) from the DUT 102 during fitting until the response signals essentially match one another. In other embodiments, respective test metrics of the device model 110 and DUT 102 are compared during fitting. In particular, one or more test metrics generated from the device model 110 are compared to equivalent test metrics generated from the DUT 102. When the generated test metrics essentially match, the device model 110 performance essentially matches the DUT 102 performance. In yet other embodiments, a comparison of both the respective response signals and one or more of the equivalent test metrics is employed.

As used herein, the term ‘essentially match’ means that items (e.g., signals, values, etc.) being compared match one another to a degree deemed acceptable according to a predetermined arbitrary criterion (e.g., as defined by a test plan). For example, the response signal \tilde{R}(t) and the response signal R(t) essentially match when the signals differ from one another by less than or equal to 0.01 dB over a specified bandwidth or within a specified time period. Similarly, a difference limit defining ‘essentially match’ may be set when comparing values determined for various test metrics. In some embodiments, the difference limit is based on specified performance criteria for the DUT 102. For example, a particular test metric is specified to include a value and a predefined tolerance around that value ((e.g., receiver gain=95 dB plus or minus 1 dB). Thus, a performance of the device model 110 and of the DUT 102 essentially match one another when the difference between respective test metrics for the device model 110 and for the DUT 102 within than the predefined tolerance.

In some embodiments, whether or not items essentially match is based on an error including, but not limited to, an average error or a root mean square (RMS) error. For example, an error may be calculated by determining an average difference and/or an RMS difference between the device model 110 output and the DUT 102 output. The difference may be determined for one or both of the response signals and a test metric. Arbitrary limits on the errors may be set to establish that the device model 110 is fitted with sufficient accuracy for a given testing situation.

Referring again to FIG. 2, the block diagram model 112 is generally a simple model of the functional features of the device type in terms of one or more signal paths through the device type. By ‘simple’ it is meant that the block diagram model 112 represents an expected behavior of the device type (or equivalently of the DUT 102) at a block diagram level under either a priori known or specified stimulus conditions. For example, the specified stimulus condition may be specified by a testing plan for the DUT 102.

The block diagram model 112 essentially captures major frequency translations and filter-like features present in the device type according to various embodiments of the present invention. The block diagram model 112 is not intended to be a detailed model of the device type behavior or the DUT 102 behavior, such as for one or both of all possible stimulus signals and all possible operational conditions. Therefore, being a simple model, according to the embodiments of the present invention, the block diagram model 112 generally does not, and is not intended to, faithfully reproduce all of the performance characteristics of an actual DUT 102, especially with respect to impairments or non-ideal characteristics thereof.

In effect, the block diagram model 112 functions as a signal ‘transformer’ or a ‘filter’ that transforms the stimulus signal S(t) into an approximation of the response signal R(t). For example, when the device type is a direct conversion receiver, the block diagram model 112 may transform an RF stimulus signal S(t) into one or more baseband response signals \hat{R}(t) (e.g., I/Q baseband signals). In another example in which the device type is an upconverter and the stimulus signal is at baseband, the block diagram model 112 may transform the baseband stimulus signal S(t) into an RF response signal \hat{R}(t). The block diagram model 112 essentially embeds in the response signal \hat{R}(t) specific information about a signal path within the device type. Moreover, in some embodiments, the embedded path-specific information essentially serves to reduce one or both of a time scale difference and frequency scale difference between the response signal R(t) from the DUT 102 and the input signal received by the difference model 114 (i.e., the block diagram model 112 response signal \hat{R}(t)).

Hereinafter, ‘one or both of a time scale difference and frequency scale difference’ is referred to as ‘time/frequency scale differences’ for simplicity only and not by way of limitation. The difference model 114 does not need to model the time/frequency scale differences between the stimulus signal S(t) and the response signal R(t). Instead, the difference model 114 has a simpler task of modeling a difference between the block diagram model 112 response \hat{R}(t) and the response signal R(t) (i.e., the actual response signal of the DUT 102).

In some embodiments, the block diagram model 112 comprises a series of interconnected functional blocks. Each functional block within the block diagram model 112 represents one or more functional blocks of a signal path within the device type. When interconnected, the functional blocks of the block diagram model 112 act on and transform the stimulus signal S(t) into a response signal \hat{R}(t) that is similar to that produced by the device type, or at least an idealized version thereof. In other words, a stimulus-response behavior of the block diagram model 112 essentially approximates a stimulus-response behavior of the device type (or DUT 102) at a block diagram level.

In some embodiments, the performance modeled by the functional blocks of the block diagram model 112 is that of an ideal element of the device type. An ‘ideal element’, as used herein, is an element that conforms to a theoretically perfect level of performance. For example, an ideal element would generally include no distortion, no non-linearity, no impairment, or other non-ideal characteristic. A gain block in the model 112 simply increases or decreases the magnitude of a signal passing through the gain block. Similarly, a mixer block in the model 112 simply produces the product of signals at a pair of inputs to the mixer block. The block diagram model 112 produces a stimulus-response characteristic representative of the device type (or DUT 102) that is essentially distortionless.

In other embodiments, the modeled expected performance of each functional block includes some element impairments that exist in an actual DUT 102. For example, the impairments may represent higher order mixing products produced by a mixer block. However, a goal of the block diagram model 112 is generally one or both of fast operation and compact implementation. Thus, the element impairments of the functional blocks of the block diagram model 112 are generally limited to ‘simple’ impairments.

As used herein, ‘simple impairments’ refers to non-ideal behavior of the element that can be implemented by relatively elementary mathematical operations and that can be readily identified and described using a priori knowledge from the block diagram and related specifications for the design and operation of the device type. For example, an estimate of the linear amplitude distortion may be available as a result of various preliminary experiments or due to a prior knowledge of the device. Similarly, an estimate of the linear phase distortion might be available. Such ‘simple impairments’ are often straightforward to add to the device model 110.

The functional blocks of the block diagram model 112 may be implemented and functionally interconnected using a commercially-available computer simulation environment such as, but not limited to, Simulink®, manufactured and distributed by Mathworks, Inc., Natack, Mass. Using such a simulation environment, individual functional blocks may be selected from a predefined set or constructed using tools provided by the simulation environment. Once selected or constructed, the blocks are interconnected using a graphics-based interconnection tool of the simulation environment, for example. Alternatively, the functional blocks and interconnections may be realized as functions of a custom-developed computer program using essentially any one of a variety of programming languages.

In other embodiments, the block diagram model 112 comprises a simulation device. As used herein, a ‘simulation device’ is a circuit or a combination of circuits and computer programs that together simulate, at a block diagram-level, the device type. For example, the simulation device may comprise a digital to analog converter (DAC) and one or more of a field programmable gate array (FPGA), a digital signal processor (DSP) circuit, and a DSP system.

In yet other embodiments, the block diagram model 112 may be another device representative of the DUT 102. For example, a ‘golden’ device may be employed as the block diagram model 112, in some embodiments. As used herein, the ‘golden’ device is a device of the same device type as DUT 102, the golden device being known to operate within acceptable parameters relative to a priori test conditions. For example, a prototype device or another previously-tested device that has passed all tests may be employed as a golden device when performing production testing of the DUT 102.

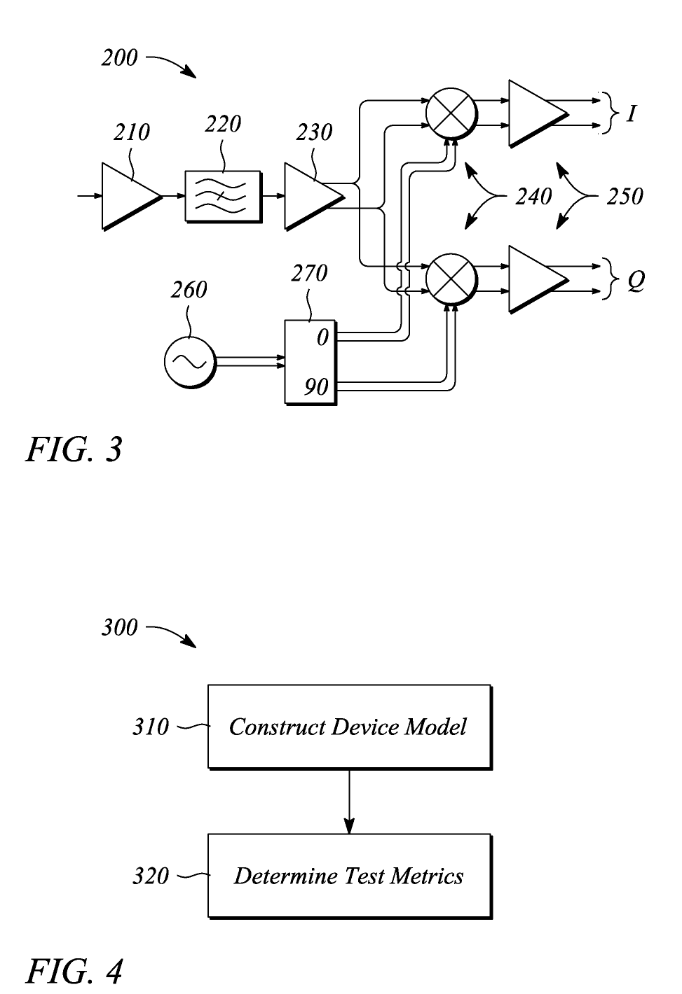

FIG. 3 illustrates a block diagram of a typical direct conversion receiver 200 used in a third generation cell phone. Referring FIG. 2, a block diagram model 112 of the exemplary direct conversion receiver (i.e., device type) illustrated in FIG. 3 may be constructed by sequentially connecting a series of functional blocks such that each block represents a corresponding block in the receiver 200 block diagram of FIG. 3. Once connected, the functional blocks of the block diagram model 112 are organized and interconnected in a manner that is similar to that of the receiver 200 block diagram. The block diagram model 112 may often be constructed directly from a functional block diagram of the device type being modeled, according to various embodiments of the present invention.

Referring again to FIG. 3, the exemplary block diagram model 112 of the receiver 200 comprises an input low noise amplifier (LNA) block corresponding to a first LNA 210 followed by a block that simulates a surface acoustic wave (SAW) filter 220 of the receiver 200. The SAW filter block is followed by a second LNA block having a differential output and corresponding to a second LNA 230 of the receiver 200. The second LNA block produces a differential signal that is processed by a pair of mixer blocks respectively corresponding to a pair of mixers 240 of the receiver 200. Outputs of the mixer blocks feed signals to a pair of variable gain amplifier (VGA) blocks which in turn produce an in-phase (I) output signal and a quadrature (Q) output signal, respectively. The VGA blocks correspond to VGAs 250 of the receiver 200. As illustrated in FIG. 3, an I-channel output of the receiver 200 is labeled ‘I’ while a Q-channel output is labeled ‘Q’. Also as illustrated in FIG. 3, components following the second LNA 230 are differential devices.

The exemplary block diagram model 112 further comprises a local oscillator (LO) block and an LO distribution block for supplying a differential LO signal to the pair of mixer blocks. The LO block corresponds to an LO 260 of the receiver 200 and the distribution block corresponds to a distribution element (e.g., differential power divider) 270 of the receiver 200. Each of the individual blocks of the exemplary block diagram model 112 simulates the element to which it corresponds. For example, the differential nature of a given element in receiver 200 may be reflected in the corresponding block of the block diagram model 112. The fully constructed block diagram model 112 has a stimulus-response characteristic that is similar to the direct conversion receiver 200, at least to the extent that the blocks of the block diagram model represent the performance characteristics of the corresponding elements of the device type.

Referring back to FIG. 2, the block diagram model 112 provides an input to the difference model 114. The block diagram model 112 essentially encodes or ‘embeds’ a priori known information regarding a structure of the device type into the device model 110. The block diagram model 112 is essentially a ‘model embedding’ of the device type signal path structure. The ‘model embedding’ represented by the block diagram model 112 is an extension of ‘embeddings’, such as a ‘delay embedding’, known and employed in non-linear time series analysis (NLTSA) modeling, for example.

Moreover, since the block diagram model 112 is a ‘simple’ model, generally available, block diagram-level, information regarding the device type is employed in constructing the model 112. This is in contrast to conventional detailed modeling of devices and device types used in device design, for example. For example, a computer aided design tool such as Advanced Design System (ADS), sold by Agilent Technologies, Inc., Palo Alto, Calif., may be used to create conventional detailed device modeling. The ADS generally employs proprietary data to produce models of a particular device type. Block diagram-level information is not generally proprietary and thus, is readily available for constructing the block diagram model 112 according to various embodiments of the present invention.

As discussed above, the difference model 114 receives the response signal \hat{R}(t) of the block diagram model 112 and produces the response signal \hat{R}(t) therefrom. In some embodiments, the difference model 114 fitting reduces a difference between the DUT response R(t) and the difference model 114 response \hat{R}(t). In some embodiments, the difference model 114 is fitted to minimize the difference. In general, the difference model 114 may comprise any model and modeling methodology that is capable of modeling the differences between the block diagram model 112 and the DUT 102.

In some embodiments, the difference model 114 is a NLTSA model and fitting is performed according to fitting methods appropriate for such NLTSA models. For example, an NLTSA model comprising polynomials may be employed as the difference model 114. Coefficients of the polynomials established during fitting are the fitted parameters of the difference model 114. In other embodiments, functions other than, or in addition to, polynomials including, but not limited to, spline basis functions, radial basis functions, and neural nets, may be employed in the NLTSA model to realize the difference model 114. In some embodiments, a nonlinear optimization is performed to establish fitted parameters of the difference model 114. For example, coefficients of the NLTSA may be established using a regression on or by a least squares fit of data representing the block diagram model 112 response signal \hat{R}(t) and the DUT 102 response signal R(t).

In some embodiments, the NLTSA-based difference model 114 is a nonlinear black-box behavioral model described by Lee Barford et al., U.S. Pat. No. 6,850,871, incorporated herein by reference in its entirety. In such embodiments, fitting is performed using embeddings of time-domain measurements of the block diagram model 112 response signal \hat{R}(t) and the DUT 102 response signal R(t). Specifically, in accordance with Barford et al., a nonlinear black-box behavioral model of a nonlinear device is produced from embeddings of time-domain measurements in which an input signal is applied to the nonlinear device, the input signal is sampled to produce input data, and a response to the input signal at the output of the device is measured to produce output data corresponding to the input data. An embedded data set is then created using a first subset of the input data and a first subset of the output data. After the embedded data set is created, a function is fitted to the embedded data set and the fitted function is verified using a second subset of the input data and a second subset of the output data. The verified fitted function is the behavioral model of the nonlinear device. In the instant invention, the ‘nonlinear device’ of Barford et al. is a virtual device represented by the difference model 114. Further, the behavioral model developed and verified according to Barford et al. is the difference model 114. Another difference model 114 and its respective fitting is described in Khoche et al., US Patent Application Publication, US 2006/0155411 A1, incorporated by reference herein.

In some embodiments, the response signal \hat{R}(t) of the block diagram model 112 is aligned with the response signal R(t) from the DUT 102 prior to being applied to and used in fitting the difference model 114. Alignment seeks to correct mismatches and accordingly reduce an effect of one or more of time alignment mismatch, phase alignment mismatch, and amplitude alignment/offset mismatch between the block diagram model 112 output and that produced by the DUT 102. In some embodiments, the alignment minimizes the effect of one or more of the mismatches. In some embodiments, the alignment with respect to one or more of time, phase, and amplitude/offset is performed in or with respect to a complex plane representation of the signals \hat{R}(t) and R(t).

For example, time alignment mismatch may be corrected by ‘resampling’ one or both of the signals \hat{R}(t) and R(t). Once resampled, data representing each of the signals is aligned. Phase alignment mismatch is corrected by ‘de-skewing’ the data, for example. In some embodiments, a simple search or an optimization may be performed to achieve the aligning and/or de-skewing. Amplitude alignment and offset mismatch is corrected by ‘rescaling’ the data and/or de-meaning the data (e.g., subtracting a mean value of the data from each data point). In some embodiments, a nonlinear optimization is performed to simultaneously correct these mismatches. Once aligned, the fitting of the difference model 114 is performed.

Returning to the direct conversion receiver illustrated in FIG. 3, an exemplary difference model 114 of one of the baseband output channels (e.g., an I-channel) generates an output Ĩ(t) comprising a portion of the difference model 114 response \tilde{R}(t) associated with the I-channel output of the exemplary direct conversion receiver. The difference model 114 generating the output Ĩ(t) may be represented in terms of a third order polynomial of input data Î(t) and \hat{Q}(t), where the input data Î(t) and \hat{Q}(t) are respectively I-channel and Q-channel portions of the response signal \hat{R}(t) of the block diagram model 112. Such a third order polynomial-based difference model 114 is given by equation (1)

$$\tilde{I} ( t ) = \frac{1}{\tilde{A}} \{ {ξ}_{1} [ A \cdot [ α \cdot [ \hat{I} ( t ) - {a}_{0} ] + β \cdot [ \hat{Q} ( t ) - {b}_{0} ] ] ] + {{ξ}_{2} [ {A}^{2} \cdot [ α \cdot [ \hat{I} ( t ) - {a}_{0} ] + β \cdot [ \hat{Q} ( t ) - {b}_{0} ] ] ]}^{2} + {{ξ}_{3} [ {A}^{3} \cdot [ α \cdot [ \hat{I} ( t ) - {a}_{0} ] + β \cdot [ \hat{Q} ( t ) - {b}_{0} ] ] ]}^{3} + \tilde{A} {\tilde{a}}_{0} \} \qquad ( 1 )$$

where terms ξ₁, ξ₂, and ξ₃ are model fitting coefficients. Further in equation (1), variables A and Ã are scale values, variables a₀, b₀ and a₀ are scalar offsets, and variables α and β are rotation coefficients. In some embodiments, the rotation coefficients α and β are related such that α is equal to cos(θ) and β is equal to sin(θ) (i.e., α=cos(θ) and β=sin(θ). Collectively, the model fitting coefficients ξ₁, ξ₂, and ξ₃, the scale values A and Ã, the scalar offsets a₀, b₀ and ã₀, and the rotation coefficients variables α and β are referred to as model parameters of the exemplary difference model 114.

In some embodiments, fitting the difference model 114 to the signals \hat{R}(t) and R(t), or data corresponding thereto, comprises determining values for each of the variables (i.e., model parameters) in equation (1). For example, a least squares fit may be performed to reduce, and in some embodiments to minimize, a difference between the difference model 114 output Ĩ(t) given by equation (1) and an I-channel portion l(t) of the DUT 102 stimulated response signal R(t).

However, in some embodiments discussed above, the response signal \hat{R}(t) of the block diagram model 112 is aligned with the response signal R(t) from the DUT 102 prior being applied to and used in fitting the difference model 114. Such alignment of the signals \hat{R}(t) and R(t) may essentially determine the scale values A and Ã, the scalar offsets a₀, b₀ and ã₀, and the rotation coefficients α and β or equivalently angle θ. In such embodiments, fitting, such as by a least squares fit or another optimization-like methodology, need determine only the model fitting coefficients ξ₁, ξ₂, and ξ₃. Note that, in general, the model parameters are determined for a particular DUT 102 (e.g., a specific direct conversion receiver) and thus, the exemplary difference model 114, once fitted, models a performance of that particular DUT 102.

Once the model parameters of the exemplary difference model 114 are determined by fitting, test metrics for the DUT may be determined from the fitted device model 110 using measurement projection. For example, consider a particular result of the exemplary difference model 114 described by equation (1) where the model parameters A=Ã=1 and the model parameters a₀=b₀=ã₀=α=β=0. Measurement projection may be used to determine a 1 dB compression point for the I-channel, for example.

In general, a 1 dB compression point may be computed using a spectral density from a single-tone test. In particular, the spectral density may be determined by computing

$$\frac{1}{T} {\int }_{0}^{T} {u}^{2} ( t ) d t$$

where u(t)=Ĩ(t) with a sinusoidal input representing the single tone. For example, a single-tone, sinusoidal input may be expressed as Ĩ(t)=Vcos(ωt) and \hat{Q}(t)=Vcos(ωt) where V is an arbitrary amplitude of the sinusoid and c an arbitrary angular frequency of the sinusoid. Then, for the above-assumed model parameters, an output power Pₒᵤₜ(·) for a single-tone test expressed as a function of the model fitting coefficients ξᵢ={ξ₁, ξ₂, ξ₃} is given by equation (2)

$${P}_{out} ( {ξ}_{i} ) = \frac{1}{16} {P}_{i n} ( 8 {ξ}_{1}^{2} + 6 {ξ}_{2}^{2} {P}_{i n} + 12 {ξ}_{1} {ξ}_{3} + 5 {ξ}_{3}^{2} {P}_{i n}^{2} ) \qquad ( 2 )$$

where a term Pᵢₙ is an input power. Given the sinusoidal input defined above, Pᵢₙ=2(V²/2)=V².

Further, to compute the 1 dB compression point, a linear power response Pₗᵢₙₑₐᵣ is compared in dB to output power Pₒᵤₜ(ξᵢ). When the output power Pₒᵤₜ(ξᵢ) differs from the linear power response Pₗᵢₙₑₐᵣ by 1 dB, the 1 dB compression point has been reached. Specifically, the linear power response Pₗᵢₙₑₐᵣ is given by

$${P}_{linear} = \frac{1}{2} {ξ}_{1}^{2} {P}_{i n} \qquad ( 3 )$$

and the 1 dB compression point P_{1dB} is given in terms of the aforementioned assumed model parameters and the model fitting coefficients ξ₁ by equation (4)

$${P}_{1 dB} ( {ξ}_{i} ) = \frac{1}{{ξ}_{3}^{2}} ( - 0.6 {ξ}_{2}^{2} - 1.2 {ξ}_{1} {ξ}_{3} - 1.054 \sqrt{\begin{matrix}0.324054 {ξ}_{2}^{4} + \\ 1.29622 {ξ}_{1} {ξ}_{2}^{2} {ξ}_{3} + {ξ}_{1}^{3} {ξ}_{3}^{2}\end{matrix}} ) \qquad ( 4 )$$

Similarly, a third order intercept point may be determined through measurement projection. The third order intercept point is defined as a point where a first order term and a third order term of a power series representation of the response signal intercept one another. By analogy to the discussion above with respect to the 1 dB compression point, a first order term P₁ and a third order term P₃ are given by

$${P}_{1} = {P}_{linear} = \frac{1}{2} {ξ}_{1}^{2} {P}_{i n}$$

$${P}_{3} = \frac{5}{16} {ξ}_{3}^{2} {P}_{i n}^{3}$$

### In turn, the third order intercept point P_{OIP3} is given by equation (5)

$$IOIP 3 = {P}_{3} = {P}_{1} ⇒ {P}_{OIP 3} = \frac{{ξ}_{1}}{{ξ}_{3}} \sqrt{\frac{8}{5}} \qquad ( 5 )$$

or in dBW, the third order intercept point P_{OIP3} is given by equation (6)

$${P}_{OIP 3}^{dBW} = {log}_{10} ( \frac{{ξ}_{1}}{{ξ}_{3}} ) + {log}_{10} \sqrt{\frac{8}{5}} + 3 \qquad ( 6 )$$

Once the model fitting coefficients ξᵢ={ξ₁, ξ₂, ξ₃} are determined by fitting, the 1 dB compression point P_{1dB} and third order intercept point P_{OIP3} are determined by measurement projection using equations (4) and (5) or (4) and (6), respectively. Moreover, both the 1 dB compression point test metric and the third order intercept point test metric for the above-described example are independent of a specific form of the stimulus signal S(t) applied to the exemplary DUT 102. In particular, both test metrics depend only on the model parameters so that measurement projection need not involve explicit application of a stimulus signal S(t) (i.e., explicit stimulation) to the fitted device model 110 subsequent to fitting. The test metrics are determined solely by extracting and utilizing model parameters of the device model 110. Of course, while the example above did not involve explicit stimulation of the fitted device model 110, such explicit stimulation may be used on one or both of other test metrics and other particular device types.

FIG. 4 illustrates a flow-chart of a method 300 of model-based testing of a device under test (DUT), according to an embodiment of the invention. The method 300 of model-based testing comprises constructing 310 a device model, the device model comprising a block diagram model and a difference model. The block diagram model models a device type representing the DUT. Once constructed, the device model emulates a stimulus-response behavior of the DUT. The method 300 of model-based testing further comprises determining 320 test metrics for the DUT from an output of the device model using measurement projection.

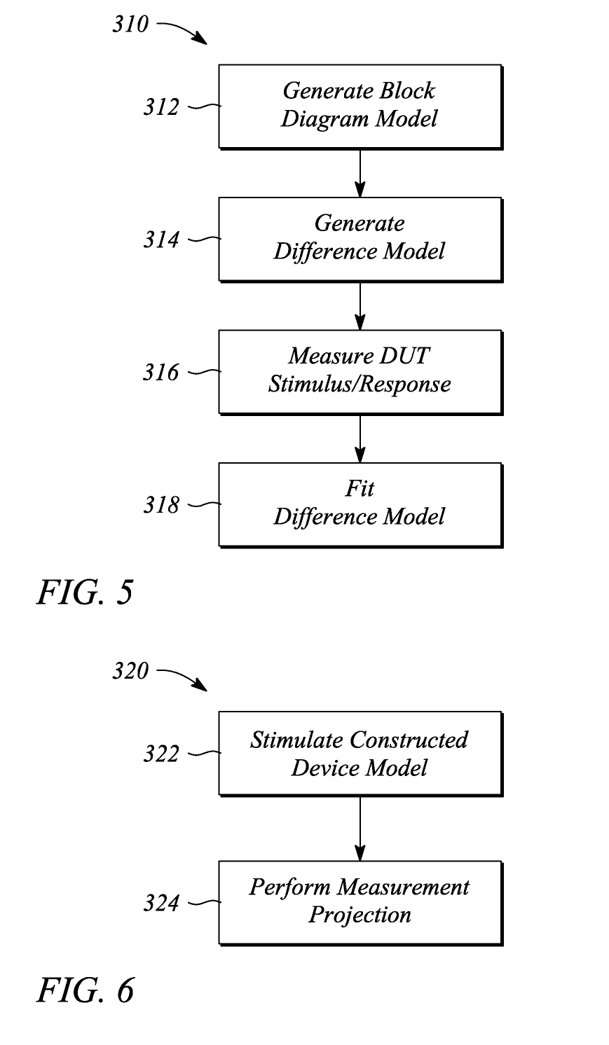

FIG. 5 illustrates a flow-chart of constructing 310 a device model of the method 300 illustrated in FIG. 4, according to an embodiment of the invention. As illustrated in FIG. 5, constructing 310 a device model comprises generating 312 a block diagram model of the device type. The block diagram model models a signal path through the device type and represents the device type at a block diagram level. In some embodiments, the block diagram model is generated using a simulation environment such as Simulink®. In some embodiments, generating 312 the block diagram model employs a priori known information regarding a block diagram-level structure of the signal path of the device type, according to a design of the device type.

Constructing 310 a device model further comprises generating 314 the difference model comprising a basis function and model parameters. Generating 314 comprises selecting the basis function and identifying the model parameters, for example. The difference model accounts for a difference between a stimulus-response behavior of the block diagram model and a stimulus-response behavior of the DUT.

Constructing 310 a device model further comprises measuring 316 a stimulus-response behavior of the DUT. Measuring 316 comprises applying a stimulus signal S(t) to the DUT and producing a stimulated response signal R(t) as a result of applying, for example.

Constructing 310 a device model further comprises fitting 318 the difference model. Fitting 318 adjusts parameters of the difference model such that a response signal \tilde{R}(t) of the difference model essentially matches the stimulated response signal R(t) of the DUT, according to some embodiments.

Fitting 318 comprises applying a stimulus signal S(t) to the block diagram model. When a stimulus signal S(t) is applied to the block diagram model, the block diagram model produces a response signal \hat{R}(t) that approximates a stimulated response signal of the device type to the extent that the block diagram model operation approximates the device type.

Fitting 318 further comprises adjusting the parameters of the difference model using the response signal \hat{R}(t) of the block diagram model and the stimulated response signal R(t) of the DUT, respectively. In some embodiments, fitting 318 also adjusts parameters of the block diagram model. Fitting 318 reduces, and in some embodiments minimizes, a difference between the response signal \tilde{R}(t) of the difference model and the stimulated response signal R(t) of the DUT. Once fitted, a stimulus-response behavior of the device model essentially matches the stimulus response behavior of the DUT.

In some embodiments, fitting 318 comprises employing an optimization such as, but not limited to, a regression to adjust the parameters. In some embodiments, the difference model is a NLTSA model and fitting 318 employs embeddings of time-domain measurements of the block diagram model response signal \hat{R}(t) and the DUT stimulated response signal R(t), respectively.

Specifically, in such embodiments, fitting 318 comprises applying the response signal \hat{R}(t) to the difference model as an input signal, and sampling the applied input signal to produce input data. Fitting 318 further comprises measuring the response signal \tilde{R}(t) produced in response to the input signal at the output of the difference model to produce output data corresponding to the input data. Fitting 318 further comprises creating an embedded data set using a first subset of the input data and a first subset of the output data and fitting a function to the embedded data set. In some embodiments, fitting 318 further comprises verifying the fitted function using a second subset of the input data and a second subset of the output data, wherein the verified fitted function is the fitted 318 difference model. See Barford et al., cited supra.

FIG. 6 illustrates a flow-chart of determining 320 test metrics of the method 300 illustrated in FIG. 4, according to an embodiment of the present invention. As illustrated in FIG. 6, determining 320 test metrics comprises stimulating 322 the constructed 310 device model. In some embodiments, the device model is stimulated 322 using the stimulus signal S(t) employed during constructing 310. In other embodiments, another stimulus signal S′(t) that is specific for a particular test metric being determined 320 is employed to stimulate 322 the device model. In yet other embodiments, a combination of the stimulus signal S(t) used during constructing 310 and another stimulus signal S′(t) is employed during device model stimulation 322. When stimulated 322, the device model produces a response signal \tilde{R}(t) at an output of the difference model.

Determining 320 further comprises performing 324 measurement projection. In some embodiments, the response signal \tilde{R}(t) is ‘projected’ into a measurement domain from which the test metrics are determined. For example, during performing 324 measurement projection, a 1 dB compression point is determined 320 by projecting results of applying a stimulus signal S(t) that has a linearly increasing magnitude as a function of time t to produce the response signal \tilde{R}(t), and observing a point at which the response signal \tilde{R}(t) deviates from a linearly increasing value by 1 dB.

In other embodiments, performing 324 measurement projection comprises extracting from the constructed 310 device model one or more parameters that characterize a target test metric. In such embodiments, stimulating 322 the constructed device model may be omitted. For example, a parameter of the device model that is established during constructing 310 may be directly or indirectly related to a target test metric. Performing 324 measurement projection may be accomplished by simply observing a value of the target test metric parameter established during constructing 310, such that a need to stimulate 322 the device model is effectively obviated. In yet other embodiments, performing 324 measurement projection comprises both employing the response signal \tilde{R}(t) and observing one or more of the parameters of the constructed 310 device model.

In some embodiments of the present invention, model-based testing is divided into two separate operations: generating a testing protocol and performing model-based testing using the testing protocol. The two separate operations may be independently performed by two separate entities at two separate sites, in some embodiments. The generated testing protocol provides a means for communicating a structure of the model-based testing between the two entities. For example, the testing protocol may be developed by an entity that is responsible for a device design (e.g., a design house). In turn, the model-based testing using the testing protocol is performed by an entity responsible for device production (e.g., a production house), for example.

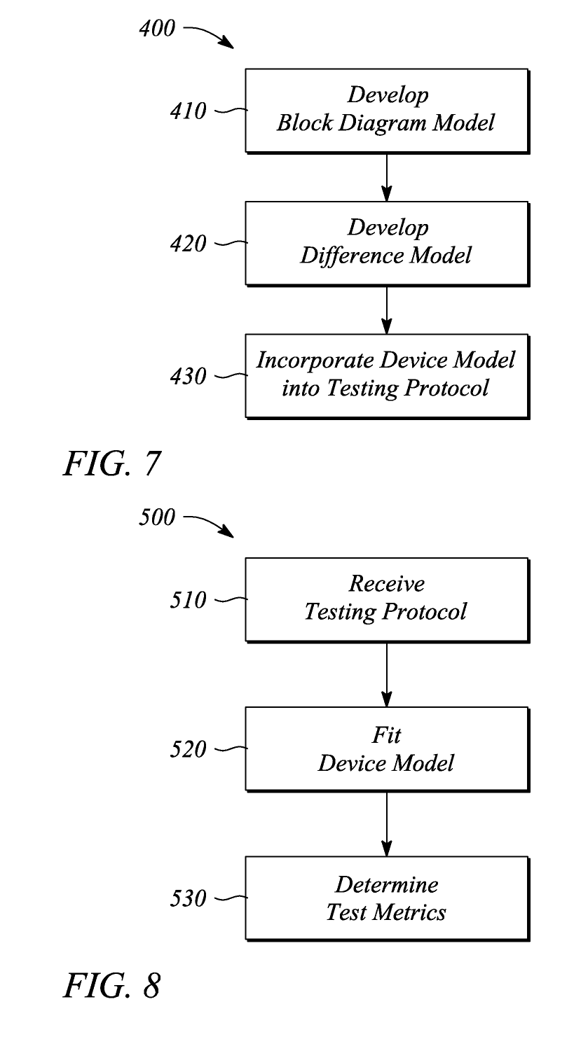

FIG. 7 illustrates a flowchart of a method 400 of generating a model-based testing protocol according to an embodiment of the present invention. In some embodiments, the testing protocol provides an input for model-based testing devices under test (DUTs) of a particular device type. In some embodiments, the testing protocol may be generated according to the method 400 by a design group or entity and then transmitted to a production entity. The testing protocol provides structure for and control of the model-based testing performed by a production house, for example.

As illustrated in FIG. 7, the method 400 of generating comprises developing 410 a block diagram model of a device type representing a device under test (DUT). The block diagram model models a signal path of the device type. In some embodiments, developing 410 a block diagram model is essentially similar to generating 312 a block diagram model described above with respect to the method 300.

The method 400 of generating further comprises developing 420 a difference model. In some embodiments, the difference model comprises a basis function and model parameters associated with the basis function. In such embodiments, developing 420 a difference model comprises selecting a basis function and identifying the associated model parameters. In some embodiments, the developed 420 difference model is essentially similar to the difference model 114 described above with respect to the testing system 100. In some embodiments, developing 420 a difference model is essentially similar to generating 314 a difference model described above with respect to the method 300.

The method 400 of generating further comprises incorporating 430 the device model into the testing protocol. The device model comprises the block diagram model and the difference model. The testing protocol with the incorporated 430 device model establishes how model-based testing of DUTs of the device type is performed, among other things.

In some embodiments (not illustrated), the method 400 of generating further comprises specifying one or more stimulus signals to be employed in testing the DUT. In some embodiments (not illustrated), the method 400 of generating further comprises defining a projection function for projecting test metrics for the DUT from an output of the device model. The projection function provides measurement projection as described above with respect to the measurement projector 120 of the testing system 100, in some embodiments.

Further in some embodiments (not illustrated), the method 400 of generating further comprises verifying the device model. The device model is verified by fitting the device model to a stimulus-response behavior of a device in a verification set of devices, in some embodiments. The device model may be fitted to stimulus-response behaviors of a plurality of devices in a verification set. Devices in the verification set have the same device type as the DUT. Moreover, the devices in the verification set exhibit a range of stimulus-response behaviors, the range being representative of an expected range of stimulus response behaviors of the DUT, according to some embodiments. The verification set may include a golden device discussed above. The verification set may also include devices having skewed stimulus-response behaviors. Verifying the device model establishes that the device model in the testing protocol is capable of modeling the device type with sufficient accuracy to support the model-based testing of production versions of the device type, for example (e.g., production DUTs).

FIG. 8 illustrates a flowchart of a method 500 of model-based testing of a device under test (DUT), according to an embodiment of the present invention. In particular, the method 500 uses a testing protocol to define the testing DUTs of a particular device type.

As illustrated in FIG. 8, the method 500 of model-based testing comprises receiving 510 a testing protocol comprising a device model that models the device type. The device model of the received 510 testing protocol comprises a block diagram model and a difference model. In some embodiments, the testing protocol is generated according to the method 400 described above.

The method 500 of model-based testing illustrated in FIG. 8 further comprises fitting 520 the device model to a stimulus-response behavior of the DUT. Fitting 520 the device model produces a fitted device model that emulates the DUT stimulus-response behavior. In a production setting where a plurality of DUTs is subjected to model-based testing, fitting 520 the device model is performed separately on each DUT of the plurality.

Fitting 520 the device model comprises measuring a stimulus-response behavior of the DUT. In some of these embodiments, measuring a stimulus-response behavior is essentially similar to measuring 312 described above with respect to the method 300. In some embodiments, fitting 520 the device model further comprises adjusting parameters of the device model until a stimulus-response behavior of the device model essentially matches the measured stimulus-response behavior of the DUT. In general, adjusting parameters may employ parameters of one or both of the block diagram model and the difference model. In some embodiments, parameters of the difference model are adjusted as described with respect to fitting 316 of the method 300.

The method 500 of model-based testing further comprises determining 530 test metrics for the DUT using measurement projection of an output of the fitted device model. In some of these embodiments, determining 530 test metrics is essentially similar to performing 324 measurement projection described above with respect to the method 300.

In some embodiments (not illustrated), skew lot studies are performed using model-based testing according to the present invention. A skew lot study is a statistical study of the effects that typical component variations have on one or both of a stimulus-response behavior of and a test metric result for a particular device type. Such statistical studies are termed “skewed lot” studies since component variations typically represent (or are skewed over) a range expected for a production lot of device of the device type. A skew lot study may be performed to discover a range of expected stimulus-responses or equivalently a range of expected test metric results for the particular device type. The results of the skew lot study act as a predictor of variations of the test metrics for devices of the device type that may be encountered in a production lot of the devices, for example. The range of expected variations obtained from the skew lot study facilitates improvements in the difference model as well as defining a tolerance for each of test metrics. The defined tolerance may be employed when testing the product lot, for example.

In an example, a plurality of prototype device with known behavioral variability is tested using the model-based testing to perform the skew lot study. Statistical analysis of test results from the model-based testing may then be used to one or both of establish an expected variability of the test metrics and improve the difference model to reflect effects of parameter variation. When the plurality of prototype devices exhibits a behavioral variability that is representative of the device type, the expected variability provides a good predictor of test metric tolerances for use in production testing of devices of the device type.

In another example, model-based testing is performed to develop a device model for the device type (e.g., a single prototype device or golden device is employed). Once the fitted device model is obtained, parameters of the device model are employed to introduce known behavioral variability for the skew lot study. In particular, the fitted device model has a stimulus-response behavior that essentially matches that of the device type. By extension, variations in parameters of the fitted device model, especially with respect to the block diagram model, are good predictors of corresponding variations in element values of a plurality of devices of the device type.

For example, a capacitor in a particular device may have a capacitance value that can be essentially any value that is within a predefined tolerance of a nominal value. The nominal value and the predefined tolerance are determined by a design of the device type. During a skew lot study using model-based testing, a capacitance value of the exemplary capacitor is varied over a range determined by the nominal value and the predefined tolerance. In some embodiments, the capacitance value is varied by varying a corresponding parameter value in the device model constructed during model-based testing according to the present invention. For example, a parameter value associated with a corresponding capacitor functional block of the block diagram model may be varied over the range. The parameter value is varied in the device model after fitting the device model to a golden device of the device type, for example.

A variation in the stimulus-response behavior of the device model is in accordance with the varied parameter value. Specifically, the variation observed in the stimulus-response behavior of the device model emulate a variation in a stimulus-response behavior that can be expected for the device type incorporating the tolerance-bounded capacitance value, for example. Further, the variations produced in the stimulus-response behavior may be projected into the test metrics for the device type. As a result, expected variations in the test metrics results for the typical variations of the skew lot study can be used to define tolerances for the test metric results for a production lot of the device type with respect to the tolerance-bounded capacitance value. Moreover, since the fitted device model is used to discover and define the tolerances, there is no need for a plurality of devices exhibit the full range of tolerance-bounded capacitance values.

In some embodiments, model-based testing system described above with respect to FIG. 1 is employed to produce the skew lot results. In particular, the measurement projector further produces skew lot results from the output of the fitted device model during a skew lot study. The skew lot results represent a range of expected variations of the test metrics for the device type representative of the DUT. In some embodiments, the method of model-based testing, described above with respect to FIG. 4, further comprises performing a skew lot study of the device type using the device model. The skew lot study comprises introducing known variations into values for parameters in the constructed device model. The skew lot study further comprises determining test metrics using measurement projection of the output of the device model with the introduced known variations. In some embodiments, the method of generating a model-based testing protocol, described above with respect to FIG. 7, further comprises performing a skew lot study of the device type to define a tolerance for a test metric. The tolerance defined by the skew lot study is incorporated into the testing protocol.

Thus, there have been described embodiments of a system and various methods involving model-based testing of a device under test (DUT) that employ a device model comprising a block diagram model and a difference model. It should be understood that the above-described embodiments are merely illustrative of some of the many specific embodiments that represent the principles of the present invention. Clearly, numerous other arrangements can be devised without departing from the scope of the present invention as defined by the following claims.

What is claimed is:

1. A model-based testing system comprising:
a device model that is fitted to a stimulus-response behavior of a device under test (DUT) to provide a fitted device model, the device model comprising a block diagram model and a difference model; and
a measurement projector producing test metrics for the DUT from an output of the fitted device model.

2. The model-based testing system of claim 1, further comprising:
a stimulus source that produces a stimulus signal, the stimulus source having an output connected to an input of the DUT and to an input of the device model,
wherein the DUT provides a response signal responsive to the stimulus signal, a combination of the stimulus signal and the response signal representing the stimulus-response behavior of the DUT.

3. The model-based testing system of claim 2, wherein the fitted device model comprises parameters of the device model adjusted to reduce a difference between a response of the device model to the stimulus signal and the response of the DUT to the stimulus signal, the parameters so adjusted being fitted parameters.

4. The model-based testing system of claim 1, wherein the block diagram model represents a signal path of a device type representative of the DUT.

5. The model-based testing system of claim 4, wherein a stimulus-response behavior of the block diagram model approximates a stimulus-response behavior of the device type such that frequency translations and signal gain features of the signal path are emulated.

6. The model-based testing system of claim 4, wherein the block diagram model comprises interconnected functional blocks, each functional block representing one or more functional elements of the signal path of the device type, wherein the interconnected functional blocks collectively exhibit a stimulus-response behavior that approximates the stimulus-response behavior of the device type at a block diagram level.

7. The model-based testing system of claim 6, wherein a functional block of the block diagram model represents a corresponding element of the device type as an ideal element.

8. The model-based testing system of claim 6, wherein a functional block of the block diagram model represents a corresponding element of the device type as an ideal element with a known impairment.

9. The model-based testing system of claim 4, wherein the block diagram model comprises a priori information regarding a structure of the signal path of the device type, the a priori information being block diagram-level information.

10. The model-based testing system of claim 1, wherein the difference model comprises a basis function and parameters associated with the basis function, the parameters being adjusted in the fitted device model, and wherein the difference model accounts for a difference between the stimulus-response behavior of the DUT and a stimulus-response behavior of the block diagram model.

11. The model-based testing system of claim 1, wherein the difference model comprises a nonlinear time-series analysis (NLTSA) model.

12. The model-based testing system of claim 1, wherein the measurement projector further produces skew lot results from the output of the fitted device model, the skew lot results representing a range of expected variations of the test metrics for a device type representative of the DUT.

13. The model-based testing system of claim 1, wherein the measurement projector further produces skew lot results from the output of the fitted device model, the skew lot results being used to improve the device model to better incorporate an effect of a parameter variation of a skew lot study.

14. The model-based testing system of claim 1, further comprising a testing protocol, the testing protocol defining a structure of the block diagram model and a structure of the difference model.

15. A method of model-based testing a device under test (DUT), the method comprising:
constructing a device model comprising a block diagram model and a difference model; and
determining test metrics for the DUT using measurement projection of an output of the device model,
wherein once constructed, a stimulus-response behavior of the device model essentially matches a stimulus-response behavior of the DUT.

16. The method of model-based testing of claim 15, wherein constructing a device model comprises:
generating the block diagram model of a device type from information regarding a block diagram-level structure of the signal path of the device type, the device type representing the DUT; and
generating the difference model comprising a basis function and model parameters, the difference model accounting for a difference between a stimulus-response behavior of the block diagram model and the stimulus-response behavior of the DUT.

17. The method of model-based testing of claim 15, wherein constructing a device model comprises:
measuring the stimulus-response behavior of the DUT; and
fitting the difference model, wherein fitting reduces a difference between the measured stimulus-response behavior of the DUT and the stimulus-response behavior of the device model.

18. The method of model-based testing of claim 17, wherein fitting the difference model comprises adjusting parameters of the difference model such that a response signal of the difference model essentially matches a response signal of the DUT.

19. The method of model-based testing of claim 15, wherein determining test metrics comprises:
stimulating the device model with one of a stimulus signal used in constructing a device model and another stimulus signal, such that stimulating the device model produces a response signal of the device model; and
performing measurement projection using the response signal to determine the test metrics.

20. The method of model-based testing of claim 15, further comprising performing a skew lot study of the device type using the device model, the skew lot study comprising:
introducing known variations into values of parameters in the device model; and
determining test metrics using measurement projection of the output of the device model.

21. A method of generating a model-based testing protocol, the method comprising:
developing a block diagram model of a device type, the block diagram model modeling a signal path of the device type and the device type representing a device under test (DUT);
developing a difference model comprising a basis function and model parameters, the difference model accounting for a difference between a stimulus-response behavior of the block diagram model and a stimulus-response behavior of the DUT; and
incorporating a device model into the testing protocol, the device model comprising the block diagram model and the difference model.

22. The method of generating of claim 21, further comprising:
defining a projection function for projecting test metrics for the DUT from an output of the device model; and
incorporating the projection function into the model-based testing protocol.

23. The method of generating of claim 21, further comprising verifying the device model.

24. The method of generating of claim 21, further comprising performing a skew lot study of the device type to one or both of define a tolerance for a test metric and improve the device model; and
incorporating the tolerance into the model-based testing protocol.

25. The method of generating of claim 21, wherein developing the block diagram model comprises interconnecting functional blocks, the functional blocks modeling one or more elements of the device type signal path, wherein the interconnected functional blocks collectively exhibit the stimulus-response behavior of the block diagram model, the stimulus-response behavior of the block diagram model approximating the stimulus-response behavior of the device type at a block diagram level.

26. The method of generating of claim 21, wherein a functional block of the block diagram model models a corresponding element of the device type as an ideal element.

27. The method of generating of claim 21 used in model-based testing of the DUT, the model-based testing comprising:
receiving the testing protocol;
fitting the device model to the stimulus-response behavior of the DUT to produce a fitted device model; and
determining test metrics for the DUT from an output of the fitted device model.

28. A method of model-based testing a device under test (DUT), the method comprising:
receiving a testing protocol comprising a device model, the device model comprising a block diagram model and a difference model; and
fitting the device model to a stimulus-response behavior of the DUT to produce a fitted device model.

29. The method of model-based testing of claim 28, wherein fitting the device model comprises:
measuring the stimulus-response behavior of the DUT; and
adjusting parameters of the device model until a stimulus-response behavior of the device model essentially matches the measured stimulus-response behavior of the DUT.

30. The method of model-based testing of claim 28, the method further comprising:
determining test metrics for the DUT using measurement projection of an output of the fitted device model.

31. The method of model-based testing of claim 28, further comprising generating the testing protocol, wherein generating comprises:
developing a block diagram model of a device type representing the DUT, the block diagram model modeling a signal path of the device type;
developing a difference model comprising a basis function and model parameters, the difference model accounting for a difference between a stimulus-response behavior of the block diagram model and the stimulus-response behavior of the DUT; and
incorporating the block diagram model and the difference model into the testing protocol.
